(19) United States
(12) Patent Application Publication
(10) Pub. No.: US 2024/0395806 A1
(43) Pub. Date: Nov. 28, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Kakeru OTSUKA, Tokyo (JP); Kosuke SAKAGUCHI, Tokyo (JP)

(73) Assignee: Mitsubishi Electric Corporation, Tokyo (JP)

(21) Appl. No.: 18/427,730

(22) Filed: Jan. 30, 2024

(30) Foreign Application Priority Data
May 24, 2023 (JP) 2023-085340

(51) Int. Cl. H01L 27/07; G01K 7/01; H01L 29/06; H01L 29/66; H01L 29/739; H01L 29/866

(52) U.S. Cl. CPC H01L 27/0727; G01K 7/01; H01L 29/0696; H01L 29/66106; H01L 29/66348; H01L 29/7397; H01L 29/866

(57) ABSTRACT

An object is to provide a technology for enabling an appropriate increase in a junction area of a p-n junction. A semiconductor device includes: a semiconductor substrate having a first main surface and a second main surface; and a polysilicon element formed on the first main surface through a first insulating film. The polysilicon element includes: a first region of a first conductivity type and a second region of a second conductivity type, the first region and the second region being formed on the first insulating film; and a third region of the second conductivity type between the first region and the second region, the third region being lower in impurity concentration than the second region. A width of the first region in a cross-sectional view varies in a direction from the second main surface to the first main surface.

### BACKGROUND OF THE INVENTION

### Field of the Invention

The present disclosure relates to a semiconductor device and a method of manufacturing the semiconductor device.

### Description of the Background Art

Recent years have seen proposals on structures in each of which a temperature sensing diode for measuring the temperature of a semiconductor device is disposed on a semiconductor substrate (e.g., Japanese Patent Application Laid-Open No. 2015-211087).

Under the conventional technology, each of a plurality of impurity regions in the temperature sensing diode in a cross-sectional view is formed vertically (i.e., in a thickness direction), and a boundary of a p-n junction vertically extends without any slope. Examples of conceivable structures for reducing a forward voltage through an increase in a junction area of the p-n junction of such a temperature sensing diode include a structure of increasing an area of the temperature sensing diode in a plan view and a structure of thickening a plurality of impurity regions in a cross-sectional view. The structure of increasing the area of the temperature sensing diode in a plan view has, however, a problem of a decrease in an effective region such as an energization region of a semiconductor device. Moreover, the structure of thickening a plurality of impurity regions in a cross-sectional view has a problem of prolonging the time for diffusing impurities.

### SUMMARY

The present disclosure has been conceived in view of the problems, and has an object of providing a technology for enabling an appropriate increase in a boundary of a p-n junction.

A semiconductor device according to the present disclosure includes: a semiconductor substrate having a first main surface and a second main surface; and a polysilicon element formed on the first main surface through a first insulating film, the semiconductor substrate including an energization region in which a first electrode is disposed closer to the first main surface and a second electrode is disposed closer to the second main surface, the polysilicon element including: a first region of a first conductivity type and a second region of a second conductivity type, the first region and the second region being formed on the first insulating film; and a third region of the second conductivity type between the first region and the second region, the third region being lower in impurity concentration than the second region, wherein a width of the first region in a cross-sectional view varies in a direction from the second main surface to the first main surface.

The junction area of the p-n junction can be appropriately increased.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a plan view illustrating a structure of a semiconductor device according to Embodiment 1;

FIG. 2 is a plan view illustrating another structure of the semiconductor device according to Embodiment 1;

FIG. 3 is a partial enlarged plan view illustrating a structure of an IGBT region of the semiconductor device according to Embodiment 1;

FIG. 4 is a cross-sectional view illustrating a structure of the IGBT region of the semiconductor device according to Embodiment 1;

FIG. 5 is a cross-sectional view illustrating a structure of the IGBT region of the semiconductor device according to Embodiment 1;

FIG. 6 is a partial enlarged plan view illustrating a structure of a diode region of the semiconductor device according to Embodiment 1;

FIG. 7 is a cross-sectional view illustrating a structure of the diode region of the semiconductor device according to Embodiment 1;

FIG. 8 is a cross-sectional view illustrating a structure of the diode region of the semiconductor device according to Embodiment 1;

FIG. 9 is a cross-sectional view illustrating a structure of a boundary region between the IGBT region and the diode region of the semiconductor device according to Embodiment 1;

FIG. 10 is a cross-sectional view illustrating a structure of a terminal region of the semiconductor device according to Embodiment 1;

FIG. 11 is a cross-sectional view illustrating a structure of the terminal region of the semiconductor device according to Embodiment 1;

FIGS. 12A and 12B are cross-sectional views illustrating a method of manufacturing the semiconductor device according to Embodiment 1;

FIGS. 13A and 13B are cross-sectional views illustrating the method of manufacturing the semiconductor device according to Embodiment 1;

FIGS. 14A and 14B are cross-sectional views illustrating the method of manufacturing the semiconductor device according to Embodiment 1;

FIGS. 15A and 15B are cross-sectional views illustrating the method of manufacturing the semiconductor device according to Embodiment 1;

FIGS. 16A and 16B are cross-sectional views illustrating the method of manufacturing the semiconductor device according to Embodiment 1;

FIGS. 17A and 17B are cross-sectional views illustrating the method of manufacturing the semiconductor device according to Embodiment 1;

FIG. 18 is a cross-sectional view illustrating a structure of the semiconductor device according to Embodiment 1;

FIG. 19 is a flowchart illustrating the method of manufacturing the semiconductor device according to Embodiment 1;

FIG. 20 is a plan view illustrating the method of manufacturing the semiconductor device according to Embodiment 1;

FIG. 21 is a plan view illustrating the method of manufacturing the semiconductor device according to Embodiment 1; and

FIG. 22 is a plan view illustrating a structure of a semiconductor device according to a modification.

### DESCRIPTION OF THE PREFERRED EMBODIMENTS

Hereinafter, embodiments will be described with reference to the accompanying drawings. The features to be described in the embodiments below are mere exemplifications, and all of the features are not necessarily essential. In the description below, identical constituent elements in a plurality of the embodiments will be denoted by the same or similar reference numerals, and different constituent elements will be mainly described. In the following description, a specific position and a specific direction such as “up”, “down”, “left”, “right”, “front”, or “back” need not always coincide with an actual position and an actual direction.

A portion higher in concentration than another portion means that, for example, an average of concentrations in the portion is higher than an average of concentrations in the other portion. Conversely, a portion lower in concentration than another portion means that, for example, an average of concentrations in the portion is lower than an average of concentrations in the other portion. Although the first conductivity type is described as n-type and the second conductivity type is described as p-type hereinafter, conversely, the first conductivity type may be p-type and the second conductivity type May be n-type. Furthermore, n⁻ represents an impurity concentration lower than that of n, and n⁺ represents an impurity concentration higher than that of n. Similarly, p⁻ represents an impurity concentration lower than that of p, and p⁺ represents an impurity concentration higher than that of p.

### Embodiment 1

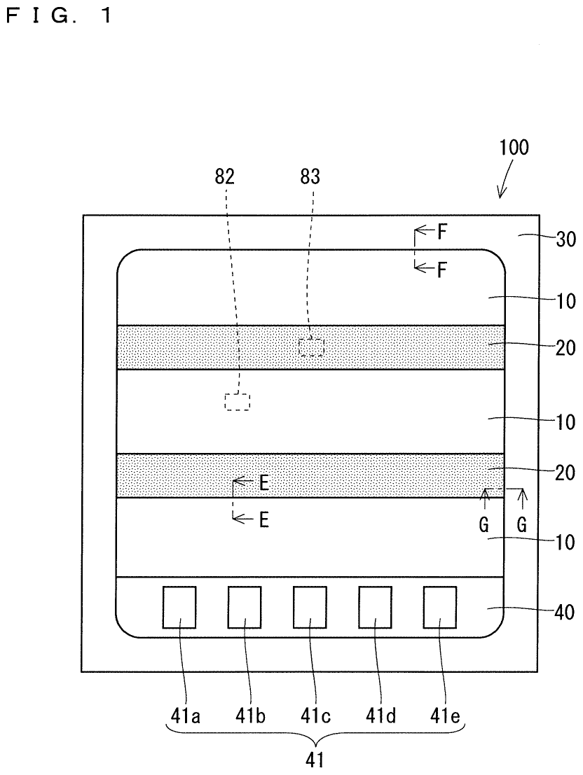

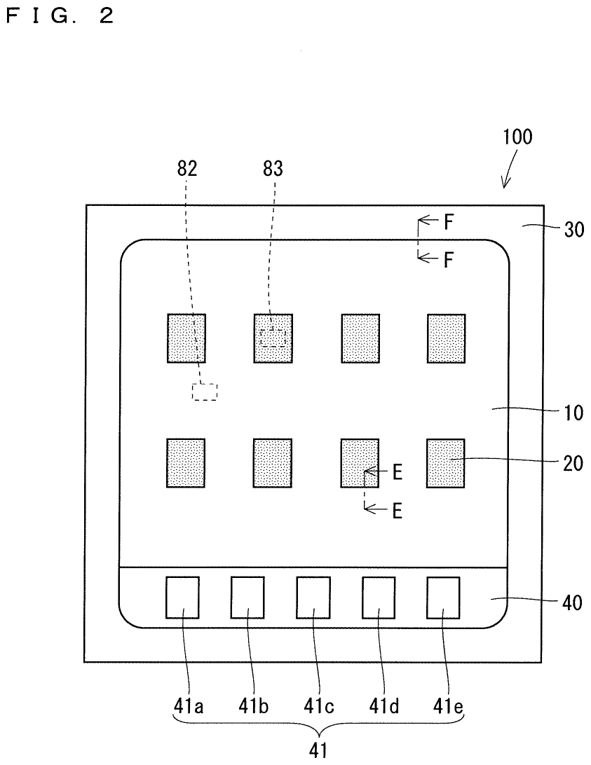

FIG. 1 is a plan view illustrating a semiconductor device including a reverse-conducting insulated gate bipolar transistor (RC-IGBT). FIG. 2 is a plan view illustrating another structure of a semiconductor device including an RC-IGBT according to Embodiment 1.

The semiconductor device according to Embodiment 1 includes not only the RC-IGBT but also a polysilicon element, which will be described later. The following will describe a structure of the RC-IGBT in the semiconductor device and then a structure of the polysilicon element. Some of the following description on the RC-IGBT does not differentiate between the RC-IGBT and the semiconductor device.

A semiconductor device 100 in FIG. 1 includes IGBT regions 10 and diode regions 20 that are arranged in stripes, and may be simply referred to as having a stripe geometry in the following description. A semiconductor device 100 in FIG. 2 includes diode regions 20 arranged in both vertical and horizontal directions, and an IGBT region 10 around the diode regions 20. This semiconductor device 100 may be simply referred to as having an island geometry in the following description. A semiconductor device should have at least one of the stripe geometry structure in FIG. 1 or the island geometry structure in FIG. 2. In this Description, at least one of A, B, C, . . . , or Z means any one of all combinations that are one or more combinations extracted from each of groups of A, B, C, . . . , and Z.

### Whole Planar Structure of Stripe Geometry

The single semiconductor device 100 in FIG. 1 includes the IGBT regions 10 and the diode regions 20. The IGBT regions 10 and the diode regions 20 extend from one end to another end of the semiconductor device 100, and are alternately arranged in stripes in a direction orthogonal to the extension direction of the IGBT regions 10 and the diode regions 20. FIG. 1 illustrates three of the IGBT regions 10 and two of the diode regions 20, and illustrates a structure of all the diode regions 20 sandwiched between the IGBT regions 10. The number of the IGBT regions 10 and the number of the diode regions 20 are not limited to these. The number of the IGBT regions 10 may be three or more, or three or less. The number of the diode regions 20 may be two or more, or two or less. The semiconductor device 100 may have a structure in which the IGBT regions 10 and the diode regions 20 in FIG. 1 are interchanged with each other such that all the IGBT regions 10 are sandwiched between the diode regions 20. Furthermore, the semiconductor device 100 may have a structure in which the single IGBT region 10 and the single diode region 20 are positioned adjacent another.

As illustrated in FIG. 1, a pad region 40 is disposed adjacent to the IGBT region 10 at the bottom of the plane of the paper. The pad region 40 is a region on which a control pad 41 for controlling the semiconductor device 100 is disposed. The IGBT regions 10 and the diode regions 20 may be collectively referred to as a cell region in the following description. A terminal region 30 for maintaining a breakdown voltage of the semiconductor device 100 is disposed around a region obtained by combining the cell region and the pad region 40. The terminal region 30 may have a known breakdown voltage maintaining structure as appropriate. For example, the breakdown voltage maintaining structure may be established by forming, on a front surface of the semiconductor device 100, a field limiting ring (FLR) surrounding the cell region with p-type termination well layers of a p-type semiconductor, or variation of lateral doping (VLD) surrounding the cell region with a p-type well layer with a concentration gradient. The number of the ring-shaped p-type termination well layers to be used for the FLR or a concentration distribution to be used for the VLD should be appropriately selected according to the design of the breakdown voltage of the semiconductor device 100. Furthermore, the p-type termination well layers may be formed on almost the whole pad region 40. Alternatively, the pad region 40 may include an IGBT cell or a diode cell.

The control pad 41 includes at least one of, for example, a current sense pad 41a, a Kelvin emitter pad 41b, a gate pad 41c, a temperature sensing diode pad 41d, or a temperature sensing diode pad 41e.

The current sense pad 41a is a control pad for detecting a current flowing through the cell region of the semiconductor device 100. The current sense pad 41a is electrically connected to the cell region so that a fraction to one several ten-thousandth of the current flowing through the entirety of the cell region flows through a part of the IGBT cell or the diode cell when a current flows through the cell region of the semiconductor device 100.

The Kelvin emitter pad 41b and the gate pad 41c are control pads to which a gate drive voltage for controlling ON/OFF of the semiconductor device 100 is applied. The Kelvin emitter pad 41b is electrically connected to a p-type base layer of the IGBT cell. The gate pad 41c is electrically connected to gate trench electrodes of the IGBT cell. The Kelvin emitter pad 41b may be electrically connected to the p-type base layer through a p⁺ type contact layer. The temperature sensing diode pads 41d and 41e are control pads electrically connected to an anode and a cathode of a temperature sensing diode of the semiconductor device 100. A voltage between the anode and the cathode of the temperature sensing diode that is disposed in the cell region and not illustrated is measured through the temperature sensing diode pads 41d and 41e. The temperature of the semiconductor device 100 is measured based on the voltage.

### Whole Planar Structure of Island Geometry

The single semiconductor device 100 in FIG. 2 includes the IGBT region 10 and the diode regions 20. The diode regions 20 are arranged side by side in the vertical and horizontal directions in the semiconductor device 100. The IGBT region 10 surrounds the diode regions 20. In other words, the plurality of diode regions 20 are formed like islands in the IGBT region 10. FIG. 2 illustrates a structure of the diode regions 20 formed in a matrix of four columns in the horizontal direction and two rows in the vertical direction on the plane of the paper. The number and the arrangement of the diode regions 20 are not limited to these. The semiconductor device 100 may have a structure in which the IGBT region 10 is interspersed with one or more of the diode regions 20 and the IGBT region 10 surrounds the diode regions 20.

As illustrated in FIG. 2, the pad region 40 is disposed adjacent to the IGBT region 10 at the bottom on the plane of the paper. The pad region 40 is a region on which the control pad 41 for controlling the semiconductor device 100 is disposed. In the description herein, the IGBT region 10 and the diode regions 20 are also collectively referred to as a cell region. The terminal region 30 for maintaining the breakdown voltage of the semiconductor device 100 is disposed around the region obtained by combining the cell region and the pad region 40. The terminal region 30 may have a known breakdown voltage maintaining structure as appropriate. For example, the breakdown voltage maintaining structure may be established by forming, on a front surface of the semiconductor device 100, the FLR surrounding the region obtained by combining the cell region and the pad region 40 with the p-type termination well layers of the p-type semiconductor, or the VLD surrounding the cell region with the p-type well layer with the concentration gradient. The number of the ring-shaped p-type termination well layers to be used for the FLR and the concentration distribution to be used for the VLD should be appropriately selected according to the design of the breakdown voltage of the semiconductor device 100. Furthermore, the p-type termination well layers may be formed on almost the whole pad region 40. Alternatively, the pad region 40 may include an IGBT cell or a diode cell.

The control pad 41 includes at least one of, for example, the current sense pad 41a, the Kelvin emitter pad 41b, the gate pad 41c, the temperature sensing diode pad 41d, or the temperature sensing diode pad 41e.

The current sense pad 41a is a control pad for detecting a current flowing through the cell region of the semiconductor device 100. The current sense pad 41a is electrically connected to the cell region so that a fraction to one several ten-thousandth of the current flowing through the entirety of the cell region flows through a part of the IGBT cell or the diode cell when a current flows through the cell region of the semiconductor device 100.

The Kelvin emitter pad 41b and the gate pad 41c are control pads to which a gate drive voltage for controlling ON/OFF of the semiconductor device 100 is applied. The Kelvin emitter pad 41b is electrically connected to a p-type base layer and an n⁺ type source layer of the IGBT cell. The gate pad 41c is electrically connected to the gate trench electrodes of the IGBT cell. The Kelvin emitter pad 41b may be electrically connected to the p-type base layer through a p⁺ type contact layer. The temperature sensing diode pads 41d and 41e are control pads electrically connected to the anode and the cathode of the temperature sensing diode of the semiconductor device 100. A voltage between the anode and the cathode of the temperature sensing diode that is disposed in the cell region and not illustrated is measured through the temperature sensing diode pads 41d and 41e. The temperature of the semiconductor device 100 is measured based on the voltage.

### IGBT Region 10

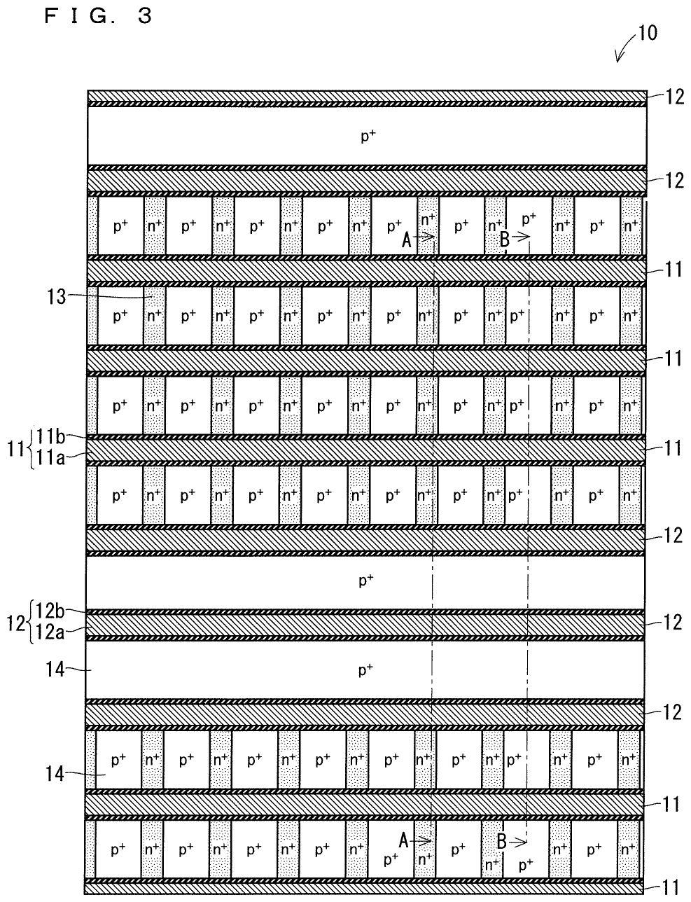

FIG. 3 is a partial enlarged plan view illustrating a structure of the IGBT region 10 of the semiconductor device 100 that is an RC-IGBT. Specifically, FIG. 3 illustrates an enlarged view of a region enclosed by a broken line 82 in the semiconductor device 100 which is illustrated in FIGS. 1 and 2.

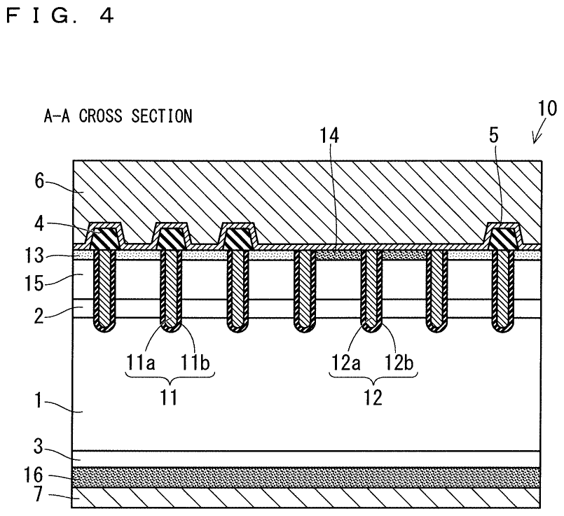

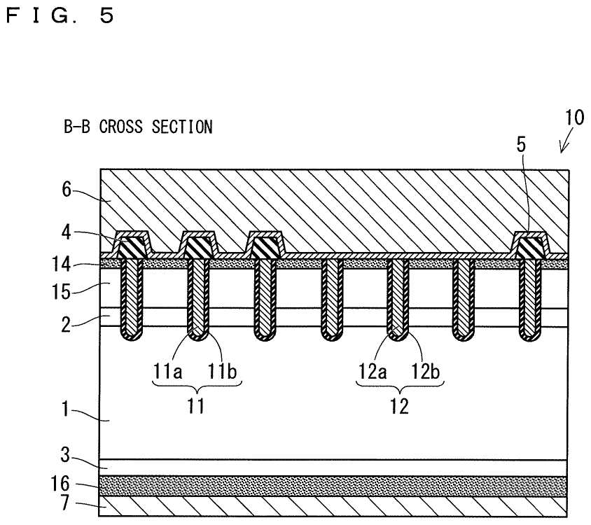

FIGS. 4 and 5 are cross-sectional views illustrating a structure of the IGBT region 10 of the semiconductor device that is the RC-IGBT. Specifically, FIG. 4 is a cross-sectional view taken along an alternate long and short dashed line A-A of the semiconductor device 100 in FIG. 3. FIG. 5 is a cross-sectional view taken along an alternate long and short dashed line B-B of the semiconductor device 100 in FIG. 3.

As illustrated in FIG. 3, the IGBT region 10 includes active trench gates 11 and dummy trench gates 12 that are arranged in stripes. In the semiconductor device 100 of FIG. 1, the active trench gates 11 and the dummy trench gates 12 extend in the longitudinal direction of the IGBT region 10. The longitudinal direction of the IGBT region 10 corresponds to that of the active trench gates 11 and the dummy trench gates 12. In contrast, there is no particular distinction between the longitudinal direction and a short direction in the IGBT region 10 in the semiconductor device 100 in FIG. 2. Thus, the horizontal direction or the vertical direction on the plane of the paper may correspond to the longitudinal direction of the active trench gates 11 and the dummy trench gates 12.

Each of the active trench gates 11 includes a gate trench electrode 11a embedded in a trench in a semiconductor substrate through a gate trench insulating film 11b. Each of the dummy trench gates 12 includes a dummy trench electrode 12a embedded in a trench in the semiconductor substrate through a dummy trench insulating film 12b. The gate trench electrodes 11a of the active trench gates 11 are electrically connected to the gate pad 41c in FIGS. 1 and 2. The dummy trench electrodes 12a of the dummy trench gates 12 are electrically connected to an emitter electrode on the front surface of the semiconductor device 100.

As illustrated in FIG. 3, n⁺ type source layers 13 are formed in contact with the gate trench insulating films 11b on both side of the active trench gates 11 in a width direction. Each of the n⁺ type source layers 13 is also referred to as an n⁺ type emitter layer depending on a semiconductor device. The n⁺ type source layer 13 is a semiconductor layer containing, for example, arsenic (As) or phosphorus (p) as n-type impurities whose concentration ranges, for example, from 1.0 E+17/cm³ to 1.0 E+20/cm³. The n⁺ type source layer 13 and a p⁺ type contact layer 14 are alternately formed in an extension direction of the active trench gates 11. The p⁺ type contact layers 14 are formed between the adjacent two dummy trench gates 12 to be in contact with the dummy trench insulating films 12b. Each of the p⁺ type contact layers 14 is a semiconductor layer containing, for example, boron or aluminum as p-type impurities whose concentration ranges, for example, from 1.0 E+15/cm³ to 1.0 E+20/cm³.

As illustrated in FIG. 3, the three dummy trench gates 12 are aligned next to the three active trench gates 11 in the IGBT region 10 of the semiconductor device 100. In addition, the three active trench gates 11 different from the aforementioned three active trench gates 11 are aligned next to the aligned three dummy trench gates 12. Thus, the IGBT region 10 has a structure in which a group of the active trench gates 11 and a group of the dummy trench gates 12 are alternately formed. Although the number of the active trench gates 11 included in one group is three in FIG. 3, the number should be one or more. Furthermore, the number of the dummy trench gates 12 included in one group may be one or more, or 0. In other words, all of the trench gates formed in the IGBT region 10 may be the active trench gates 11.

FIG. 4 is a cross-sectional view of the IGBT region 10 which is taken along the alternate long and short dashed line A-A of the semiconductor device 100 in FIG. 3. The semiconductor device 100 includes an n⁻ type drift layer 1 that is a part of the semiconductor substrate. The n⁻ type drift layer 1 is a semiconductor layer containing, for example, arsenic or phosphorus as n-type impurities whose concentration ranges, for example, from 1.0 E+12/cm³ to 1.0 E+15/cm³. The n⁺ type source layer 13 is higher in n-type impurity concentration than the n⁻ type drift layer 1.

In FIG. 4, the semiconductor substrate ranges from the n⁺ type source layer 13 and the p⁺ type contact layer 14 to a p-type collector layer 16. The p-type collector layer 16 is also referred to as a p-type drain layer depending on a semiconductor device. In FIG. 4, the top end of the n⁺ type source layer 13 and the p⁺ type contact layer 14 on the plane of the paper will be referred to as a front surface that is a first main surface of the semiconductor substrate, and the bottom end of the p-type collector layer 16 on the plane of the paper will be referred to as a back surface that is a second main surface of the semiconductor substrate. The semiconductor device 100 includes the n⁻ type drift layer 1 between the front surface and the back surface facing the front surface, in the IGBT region 10 of the cell region. The semiconductor substrate may include, for example, at least one of a wafer or an epitaxial growth layer. The semiconductor substrate may include a wide bandgap semiconductor (e.g., silicon carbide (SiC), gallium nitride (GaN), or diamond) that can stably operate at high temperatures.

As illustrated in FIG. 4, an n-type carrier storage layer 2 higher in n-type impurity concentration than the n⁻ type drift layer 1 is formed on the front surface of the n⁻ type drift layer 1 in the IGBT region 10. The n-type carrier storage layer 2 is a semiconductor layer containing, for example, arsenic or phosphorus as n-type impurities whose concentration ranges, for example, from 1.0 E+13/cm³ to 1.0 E+17/cm³. The semiconductor device 100 may have a structure which excludes the n-type carrier storage layer 2 and in which the n⁻ type drift layer 1 is formed in a region of the n-type carrier storage layer 2 illustrated in FIG. 4. The n-type carrier storage layer 2 can reduce a conduction loss when a current flows through the IGBT region 10. The n-type carrier storage layer 2 and the n⁻ type drift layer 1 may be collectively referred to as a drift layer.

The n-type carrier storage layer 2 is formed by ion implanting n-type impurities into the semiconductor substrate including the n⁻ type drift layer 1 and diffusing, through annealing, the implanted n-type impurities into the semiconductor substrate.

The p-type base layer 15 is formed on the front surface of the n-type carrier storage layer 2. The p-type base layer 15 is a semiconductor layer containing, for example, boron or aluminum as p-type impurities whose concentration ranges, for example, from 1.0 E+12/cm³ to 1.0 E+19/cm³. The p-type base layer 15 is in contact with the gate trench insulating films 11b of the active trench gates 11.

The n⁺ type source layer 13 in contact with the gate trench insulating films 11b of the active trench gates 11 is formed in a part of a region on the front surface of the p-type base layer 15. The p⁺ type contact layer 14 is selectively formed in the remaining region on the front surface of the p-type base layer 15. The n⁺ type source layer 13 and the p⁺ type contact layer 14 are formed as the front surface of the semiconductor substrate. The p⁺ type contact layer 14 is a region higher in p-type impurity concentration than the p-type base layer 15. When there is need to distinguish between the p⁺ type contact layer 14 and the p-type base layer 15, the p⁺ type contact layers 14 and the p-type base layer 15 may be referred to by their separate names. When the distinction is not necessary, the p⁺ type contact layer 14 and the p-type base layer 15 may be collectively referred to as a p-type base layer.

Furthermore, the semiconductor device 100 includes, on the back surface of the n⁻ type drift layer 1, an n-type buffer layer 3 higher in n-type impurity concentration than the n⁻ type drift layer 1. The n-type buffer layer 3 suppresses punch-through of a depletion layer extending from the p-type base layer 15 toward the back surface when the semiconductor device 100 is in an OFF state. The n-type buffer layer 3 may be formed by implanting, for example, one of or both of phosphorus (P) and proton (H⁺). The n-type buffer layer 3 has n type impurity concentration that ranges, for example, from 1.0E+12/cm³ to 1.0 E+18/cm³. The semiconductor device 100 may have a structure which excludes the n-type buffer layer 3 and in which the n⁻ type drift layer 1 is formed in a region of the n-type buffer layer 3 illustrated in FIG. 4. The n-type buffer layer 3 and the n⁻ type drift layer 1 may be collectively referred to as a drift layer.

The semiconductor device 100 includes a p-type collector layer 16 on the back surface of the n-type buffer layer 3. In other words, the p-type collector layer 16 is formed between the n⁻ type drift layer 1 and the back surface of the semiconductor substrate. The p-type collector layer 16 is a semiconductor layer containing, for example, boron or aluminum as p-type impurities whose concentration ranges, for example, from 1.0 E+16/cm³ to 1.0 E+20/cm³. The p-type collector layer 16 is formed as the back surface of the semiconductor substrate. The p-type collector layer 16 may be formed not only in the IGBT region 10 but also in the terminal region 30. A portion of the p-type collector layer 16 that is formed in the terminal region 30 is a p-type terminal collector layer 16a as will be described later. A portion of the p-type collector layer 16 may extend beyond the IGBT region 10 and enter the diode region 20.

As illustrated in FIG. 4, the IGBT region 10 of the semiconductor device 100 includes the trenches penetrating the p-type base layer 15 from the front surface of the semiconductor substrate and reaching the n⁻ type drift layer 1. The active trench gates 11 are each formed by embedding the gate trench electrode 11a in some of the trenches through the gate trench insulating film 11b. The gate trench electrodes 11a face the n⁻ type drift layer 1 through the gate trench insulating films 11b. The dummy trench gates 12 are each formed by embedding the dummy trench electrode 12a in some of the trenches through the dummy trench insulating film 12b. The dummy trench electrodes 12a face the n⁻ type drift layer 1 through the dummy trench insulating films 12b.

The gate trench insulating films 11b of the active trench gates 11 are in contact with the p-type base layer 15 and the n⁺ type source layer 13. When a gate drive voltage is applied to the gate trench electrodes 11a, a channel is formed in the p-type base layer 15 that is in contact with the gate trench insulating films 11b of the active trench gates 11.

As illustrated in FIG. 4, an interlayer insulating film 4 is formed on the gate trench electrodes 11a of the active trench gates 11. A barrier metal 5 is formed on a region without the interlayer insulating film 4 on the front surface of the semiconductor substrate, and on the interlayer insulating film 4. The barrier metal 5 may be, for example, a conductor containing titanium (Ti), e.g., a conductor made of titanium nitride or TiSi obtained by alloying titanium with silicon (Si). As illustrated in FIG. 4, the barrier metal 5 is in Ohmic contact with and electrically connected to the n⁺ type source layer 13, the p⁺ type contact layer 14, and the dummy trench electrodes 12a. Furthermore, the interlayer insulating film 4 electrically insulates the barrier metal 5 from the gate trench electrodes 11a.

An emitter electrode 6 is disposed on the barrier metal 5. The emitter electrode 6 may be made of, for example, an aluminum alloy such as an aluminum silicon alloy (an Al—Si based alloy). The emitter electrode 6 may also be an electrode in which, on an electrode made of an aluminum alloy, a metal film with a plurality of layers on each of which a plated film is formed by electroless plating or electroplating. The plated films formed by electroless plating or electroplating may be, for example, nickel (Ni) plated films. When the semiconductor device 100 includes a fine region between the emitter electrode 6 and the adjacent interlayer insulating film 4 and the fine region is not sufficiently embedded by the emitter electrode 6, a tungsten film with embedded properties better than those of the emitter electrode 6 may be disposed on the fine region and then the emitter electrode 6 may be disposed on the tungsten film. The emitter electrode 6 may be disposed on the n⁺ type source layer 13, the p⁺ type contact layer 14, and the dummy trench electrodes 12a without the barrier metal 5. Furthermore, the barrier metal 5 may be disposed only on an n-type semiconductor layer such as the n⁺ type source layer 13. The barrier metal 5 and the emitter electrode 6 may be collectively referred to as an emitter electrode.

Although FIG. 4 illustrates a structure without the interlayer insulating film 4 on the dummy trench electrodes 12a of the dummy trench gates 12, the interlayer insulating film 4 may be formed on the dummy trench electrodes 12a of the dummy trench gates 12 in a cross-sectional portion of FIG. 4. When the interlayer insulating film 4 is formed on the dummy trench electrodes 12a of the dummy trench gates 12 in the cross-sectional portion of FIG. 4, the emitter electrode 6 should be electrically connected to the dummy trench electrodes 12a in another cross-sectional portion.

A collector electrode 7 is disposed on the back surface of the p-type collector layer 16. The collector electrode 7 may be made of an aluminum alloy, and include a plurality of layers containing an aluminum alloy and including plated films, similarly to the emitter electrode 6. The collector electrode 7 may have a structure different from that of the emitter electrode 6. The collector electrode 7 is in Ohmic contact with and electrically connected to the p-type collector layer 16.

FIG. 5 is a cross-sectional view of the IGBT region 10 which is taken along the alternate long and short dashed line B-B of the semiconductor device 100 in FIG. 3. A cross-sectional portion taken along the alternate long and short dashed line B-B in FIG. 5 does not include the n⁺ type source layer 13 that is in contact with the active trench gates 11 and is formed on the front surface of the semiconductor substrate, unlike the cross-sectional portion taken along the alternate long and short dashed line A-A in FIG. 4. In other words, the n⁺ type source layer 13 in FIG. 3 is selectively formed on the front surface of a p-type base layer. The p-type base layer herein includes the p-type base layer 15 and the p⁺ type contact layer 14.

### Diode Region 20

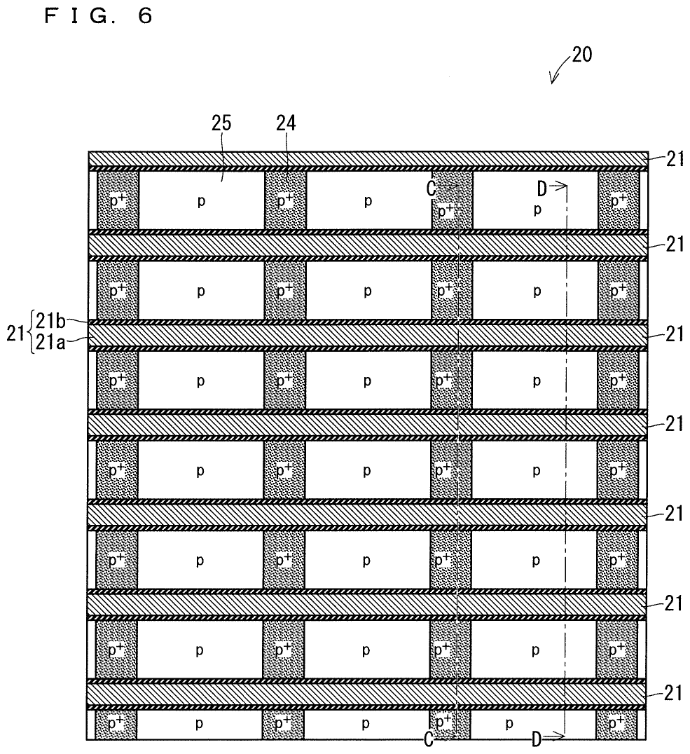

FIG. 6 is a partial enlarged plan view illustrating a structure of the diode region 20 of the semiconductor device that is the RC-IGBT. Specifically, FIG. 6 illustrates an enlarged view of a region enclosed by a broken line 83 in the semiconductor device 100 in FIGS. 1 and 2.

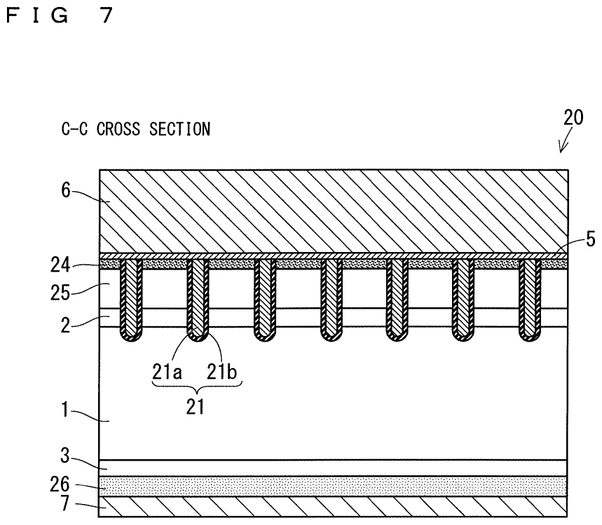

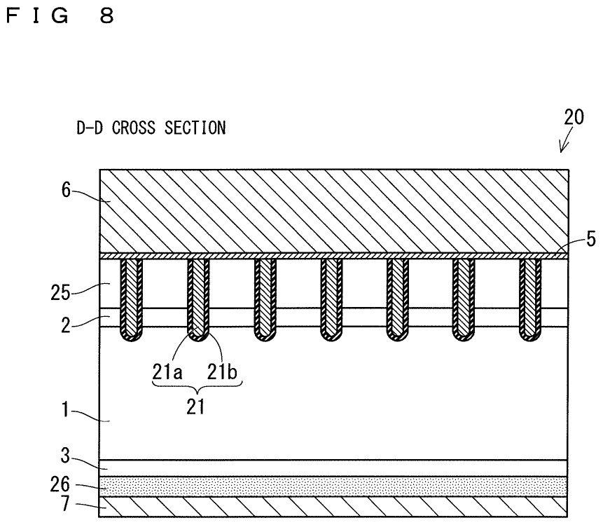

FIGS. 7 and 8 are cross-sectional views each illustrating a structure of the diode region 20 of the semiconductor device that is the RC-IGBT. Specifically, FIG. 7 illustrates a cross-sectional view taken along an alternate long and short dashed line C-C of the semiconductor device 100 in FIG. 6. FIG. 8 illustrates a cross-sectional view taken along an alternate long and short dashed line D-D of the semiconductor device 100 in FIG. 6.

Diode trench gates 21 extend from one end to another end opposite to the one end in the diode region 20 of the cell region, along the front surface of the semiconductor device 100. Each of the diode trench gates 21 includes a diode trench electrode 21a embedded in a trench of the diode region 20 through a diode trench insulating film 21b. The diode trench electrodes 21a face the n⁻ type drift layer 1 through the diode trench insulating films 21b.

P⁺ type contact layers 24 and p-type anode layers 25 lower in p-type impurity concentration than the p⁺ type contact layer 24 are formed between the adjacent two diode trench gates 21. Each of the p⁺ type contact layers 24 is a semiconductor layer containing, for example, boron or aluminum as p-type impurities whose concentration ranges, for example, from 1.0 E+15/cm³ to 1.0 E+20/cm³. Each of the p-type anode layers 25 is a semiconductor layer containing, for example, boron or aluminum as p-type impurities whose concentration ranges, for example, from 1.0 E+12/cm³ to 1.0 E+19/cm³. The p⁺ type contact layer 24 and the p-type anode layer 25 are alternately disposed in the longitudinal direction of the diode trench gates 21.

FIG. 7 is a cross-sectional view of the diode region 20 which is taken along the alternate long and short dashed line C-C of the semiconductor device 100 in FIG. 6. The diode region 20 in the semiconductor device 100 also includes the n⁻ type drift layer 1 that is the part of the semiconductor substrate, similarly to the IGBT regions 10. The n⁻ type drift layer 1 in the diode region 20 and the n⁻ type drift layer 1 in the IGBT region 10 are continuously and integrally formed in the same semiconductor substrate.

In FIG. 7, the semiconductor substrate ranges from the p⁺ type contact layer 24 to an n⁺ type cathode layer 26. In FIG. 7, the top end of the p⁺ type contact layer 24 on the plane of the paper will be referred to as a front surface of the semiconductor substrate, and the bottom end of the n⁺ type cathode layer 26 on the plane of the paper will be referred to as a back surface of the semiconductor substrate. The front surface of the diode region 20 and the front surface of the IGBT region 10 are included in the same surface, and the back surface of the diode region 20 and the back surface of the IGBT region 10 are included in the same surface.

As illustrated in FIG. 7, the n-type carrier storage layer 2 is formed on the front surface of the n⁻ type drift layer 1 and the n-type buffer layer 3 is formed on the back surface of the n⁻ type drift layer 1 in the diode region 20, similarly to the IGBT region 10. The n-type carrier storage layer 2 and the n-type buffer layer 3 that are formed in the diode region 20 may have the same structure as those formed in the IGBT region 10. The n-type carrier storage layer 2 need not be necessarily formed in the IGBT region 10 and the diode region 20. For example, the semiconductor device 100 may have a structure in which the n-type carrier storage layer 2 is formed not in the diode region 20 but in the IGBT region 10. The n⁻ type drift layer 1, the n-type carrier storage layer 2, and the n-type buffer layer 3 may be collectively referred to as a drift layer, similarly to the IGBT region 10.

The p-type anode layer 25 is formed on the front surface of the n-type carrier storage layer 2. The p-type anode layer 25 is formed between the n⁻ type drift layer 1 and the front surface of the semiconductor device 100. The p-type anode layer 25 and the p-type base layer 15 in the IGBT region 10 may be formed simultaneously by making the p-type anode layer 25 identical in p-type impurity concentration to the p-type base layer 15. Furthermore, the p-type impurity concentration of the p-type anode layer 25 may be lower than that of the p-type base layer 15 in the IGBT region 10 to reduce an amount of holes to be implanted into the diode region 20 during a diode operation. Reduction of the amount of holes to be implanted during the diode operation can reduce a recovery loss during the diode operation.

The p⁺ type contact layer 24 is formed on the front surface of the p-type anode layer 25. The p-type impurity concentration of the p⁺ type contact layer 24 may be identical or different from that of the p⁺type contact layer 14 in the IGBT region 10. The p⁺ type contact layer 24 is formed as the front surface of the semiconductor substrate. When the p⁺ type contact layer 24 is a region higher in p-type impurity concentration than the p-type anode layer 25 and there is need to distinguish between the p⁺ type contact layer 24 and the p-type anode layer 25, the p⁺ type contact layer 24 and the p-type anode layer 25 may be referred to by their separate names. When the distinction is not necessary, the p⁺ type contact layer 24 and the p-type anode layer 25 may be collectively referred to as a p-type anode layer.

The semiconductor device 100 includes the n⁺ type cathode layer 26 on the back surface of the n-type buffer layer 3. In other words, the n⁺ type cathode layer 26 is formed between the n⁻ type drift layer 1 and the back surface of the semiconductor device 100. The n⁺ type cathode layer 26 is a semiconductor layer containing, for example, arsenic or phosphorus as n-type impurities whose concentration ranges, for example, from 1.0 E+16/cm³ to 1.0 E+21/cm³. The n⁺ type cathode layer 26 is formed partly or entirely in the diode region 20. The n⁺ type cathode layer 26 is formed as the back surface of the semiconductor substrate. Though not illustrated in FIG. 7, further selectively implanting p-type impurities into a part of the region in which the n⁺ type cathode layer 26 is formed may form a p-type cathode layer that is a p-type semiconductor.

Though not illustrated in FIG. 7, the n⁺ type cathode layer 26 and a p⁺ type cathode layer may be formed on the back surface of the n-type buffer layer 3, and formed alternately in a surface direction of the semiconductor substrate. A diode formed in such a manner is referred to as a relaxed field of cathode (RFC) diode.

As illustrated in FIG. 7, the diode region 20 of the semiconductor device 100 includes the trenches penetrating the p-type anode layer 25 from the front surface of the semiconductor substrate and reaching the n⁻ type drift layer 1. Each of the diode trench gates 21 includes the diode trench electrode 21a embedded in a trench in the diode region 20 through the diode trench insulating film 21b. The diode trench electrodes 21a face the n⁻ type drift layer 1 through the diode trench insulating films 21b.

As illustrated in FIG. 7, the barrier metal 5 is formed on the diode trench electrodes 21a and the p⁺ type contact layer 24. The barrier metal 5 is in Ohmic contact with and electrically connected to the diode trench electrodes 21a and the p⁺ type contact layer 24. The barrier metal 5 may have the same structure as that of the barrier metal 5 in the IGBT region 10.

The emitter electrode 6 is disposed on the barrier metal 5. The emitter electrode 6 disposed in the diode region 20 is formed continuously with the emitter electrode 6 in the IGBT region 10. The diode trench electrodes 21a and the p⁺ type contact layer 24 may be in Ohmic contact with the emitter electrode 6 without through the barrier metal 5, similarly to the IGBT region 10.

Although FIG. 7 illustrates a structure without the interlayer insulating film 4 on the diode trench electrodes 21a of the diode trench gates 21 unlike FIG. 4, the interlayer insulating film 4 may be formed on the diode trench electrodes 21a in a cross-sectional portion of FIG. 7. When the interlayer insulating film 4 is formed on the diode trench electrodes 21a of the diode trench gates 21 in the cross-sectional portion of FIG. 7, the emitter electrode 6 should be electrically connected to the diode trench electrodes 21a in another cross-sectional portion.

The collector electrode 7 is disposed on the back surface of the n⁺ type cathode layer 26. The collector electrode 7 disposed in the diode region 20 is formed continuously with the collector electrode 7 in the IGBT region 10, similarly to the emitter electrode 6. The collector electrode 7 is in Ohmic contact with and electrically connected to the n⁺ type cathode layer 26.

FIG. 8 is a cross-sectional view of the diode region 20 which is taken along the alternate long and short dashed line D-D of the semiconductor device 100 in FIG. 6. In a cross-sectional portion along the alternate long and short dashed line D-D in FIG. 8, the p-type anode layer 25 is formed as the front surface of the semiconductor substrate, without the p⁺ type contact layer 24 between the p-type anode layer 25 and the barrier metal 5, unlike the cross-sectional portion along the alternate long and short dashed line C-C in FIG. 7. In other words, the p⁺ type contact layer 24 in FIG. 7 is selectively formed on the front surface of the p-type anode layer 25.

### Boundary Region Between IGBT Region 10 and Diode Region 20

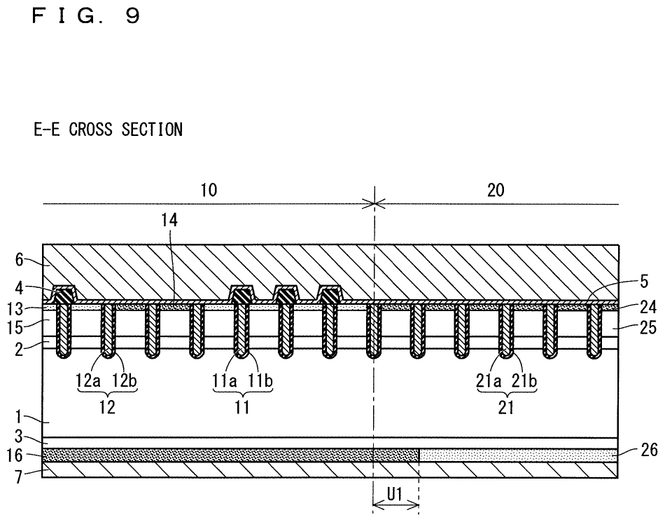

FIG. 9 is a cross-sectional view illustrating a structure of a boundary region between the IGBT region 10 and the diode region 20 of the semiconductor device that is the RC-IGBT. Specifically, FIG. 9 illustrates a cross-sectional view taken along an alternate long and short dashed line E-E of the semiconductor device 100 in FIGS. 1 and 2.

As illustrated in FIG. 9, the p-type collector layer 16 formed on the back surface in the IGBT region 10 is adjacent to the n⁺ type cathode layer 26 formed on the back surface in the diode region 20 in the surface direction of the semiconductor substrate. Furthermore, the p-type collector layer 16 extends toward the diode region 20 beyond a boundary between the IGBT region 10 and the diode region 20 by a distance U1.

As such, extension of the p-type collector layer 16 toward the diode region 20 can increase a distance between the n⁺ type cathode layer 26 in the diode region 20 and each of the active trench gates 11. This can prevent a current from flowing from the channel formed adjacent to the active trench gates 11 in the IGBT region 10 to the n⁺ type cathode layer 26, even when the gate drive voltage is applied to the gate trench electrodes 11a during a freewheeling diode operation. The distance U1 may be, for example, 100 μm. The distance U1 may be zero or a distance shorter than 100 μm, depending on usage of the semiconductor device 100 that is the RC-IGBT.

### Terminal Region 30

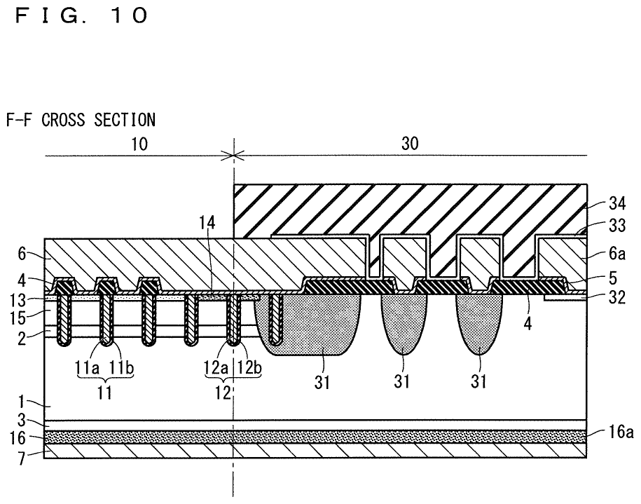

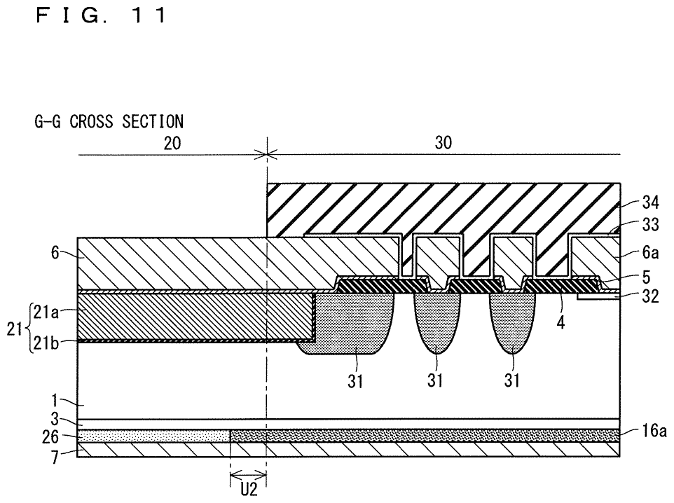

FIGS. 10 and 11 are cross-sectional views each illustrating a structure of the terminal region 30 of the semiconductor device 100 that is the RC-IGBT. Specifically, FIG. 10 is a cross-sectional view taken along an alternate long and short dashed line F-F in FIGS. 1 and 2, and is a cross-sectional view from the IGBT region 10 to the terminal region 30. Furthermore, FIG. 11 is a cross-sectional view taken along an alternate long and short dashed line G-G in FIG. 1, and is a cross-sectional view from the diode region 20 to the terminal region 30.

As illustrated in FIGS. 10 and 11, the terminal region 30 of the semiconductor device 100 includes the n⁻ type drift layer 1 between the front surface and the back surface of the semiconductor substrate. The front surface and the back surface of the terminal region 30 are included in the same surfaces as those of the IGBT region 10 and the diode region 20. The n⁻ type drift layer 1 in the terminal region 30 has the same structure as those of the IGBT region 10 and the diode region 20, and is continuously and integrally formed with those of the IGBT region 10 and the diode region 20.

P-type terminal well layers 31 are selectively formed closer to the front surface of the n⁻ type drift layer 1, that is, between the front surface of the semiconductor substrate and the n⁻ type drift layer 1. The p-type terminal well layers 31 are semiconductor layers containing, for example, boron or aluminum as p-type impurities whose concentration ranges, for example, from 1.0 E+14/cm³ to 1.0 E+19/cm³. The p-type terminal well layers 31 are formed to surround the cell region including the IGBT region 10 and the diode region 20. The p-type terminal well layers 31 are shaped like a plurality of rings. The number of the p-type terminal well layers 31 is appropriately selected according to the design of the breakdown voltage of the semiconductor device 100. Furthermore, an n⁺ channel stopper layer 32 is formed further around an outer edge of the p-type terminal well layers 31 to surround the p-type terminal well layers 31 in a plan view.

The p-type terminal collector layer 16a is formed between the n⁻ type drift layer 1 and the back surface of the semiconductor substrate in the terminal region 30. The p-type terminal collector layer 16a is continuously and integrally formed with the p-type collector layer 16 in the IGBT region 10 of the cell region. Thus, the p-type collector layer 16 including the p-type terminal collector layer 16a may be referred to as a p-type collector layer.

In the structure of the semiconductor device 100 in FIG. 1 in which the diode regions 20 are adjacent to the terminal region 30, an end of the p-type terminal collector layer 16a closer to the diode region 20 extends beyond the diode region 20 by a distance U2 as illustrated in FIG. 11. This structure can increase a distance between the n⁺ type cathode layer 26 in the diode region 20 and each of the p-type terminal well layers 31. This can prevent the p-type terminal well layers 31 from operating as an anode of a diode. The distance U2 may be, for example, 100 μum.

The collector electrode 7 is disposed on the back surface of the semiconductor substrate. The collector electrode 7 is continuously and integrally formed from the cell region including the IGBT region 10 and the diode region 20 to the terminal region 30.

The emitter electrode 6 continuous from the cell region, and terminal electrodes 6a structurally separated from the emitter electrode 6 are formed on the front surface of the semiconductor substrate in the terminal region 30. The emitter electrode 6 is electrically connected to the terminal electrodes 6a through a semi-insulating film 33. The semi-insulating film 33 may be, for example, a semi-insulating silicon nitride (sinSIN) film. The terminal electrodes 6a are electrically connected to the p-type terminal well layers 31, and the n⁺ channel stopper layer 32 through contact holes in the interlayer insulating film 4 on the front surface in the terminal region 30. Furthermore, the terminal region 30 includes a terminal protective film 34 covering the emitter electrode 6, the terminal electrodes 6a, and the semi-insulating film 33. The terminal protective film 34 is made of, for example, a polyimide.

### Method of Manufacturing RC-IGBT

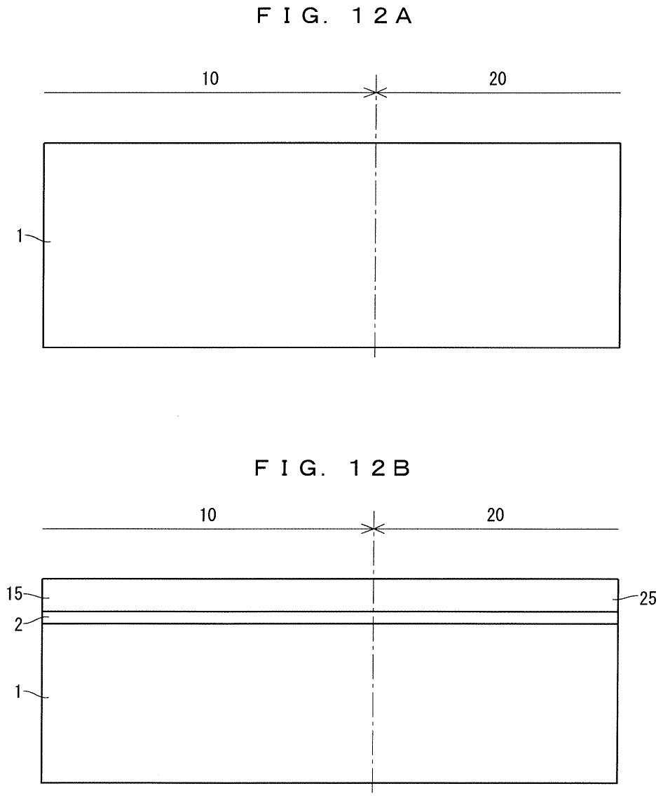

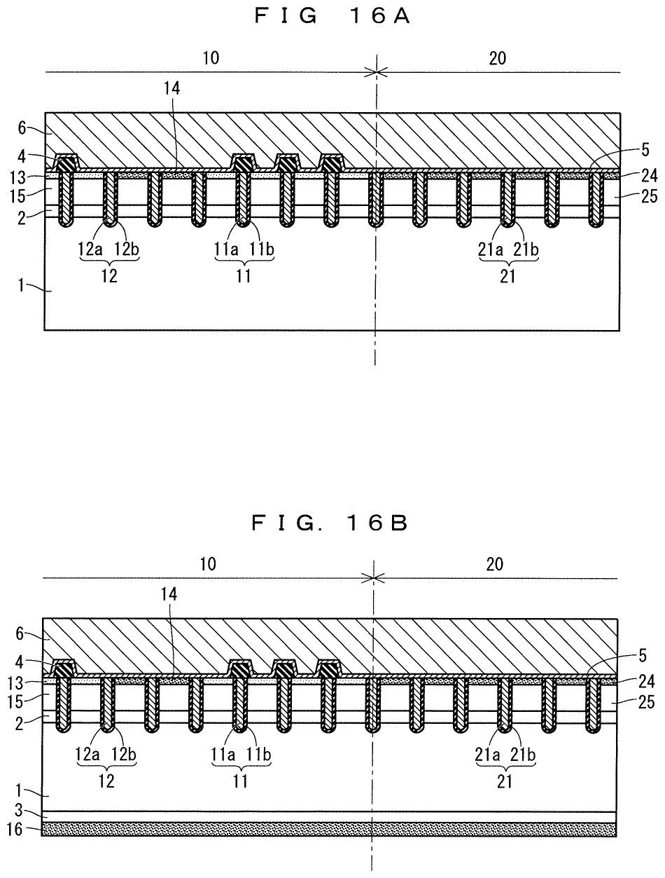

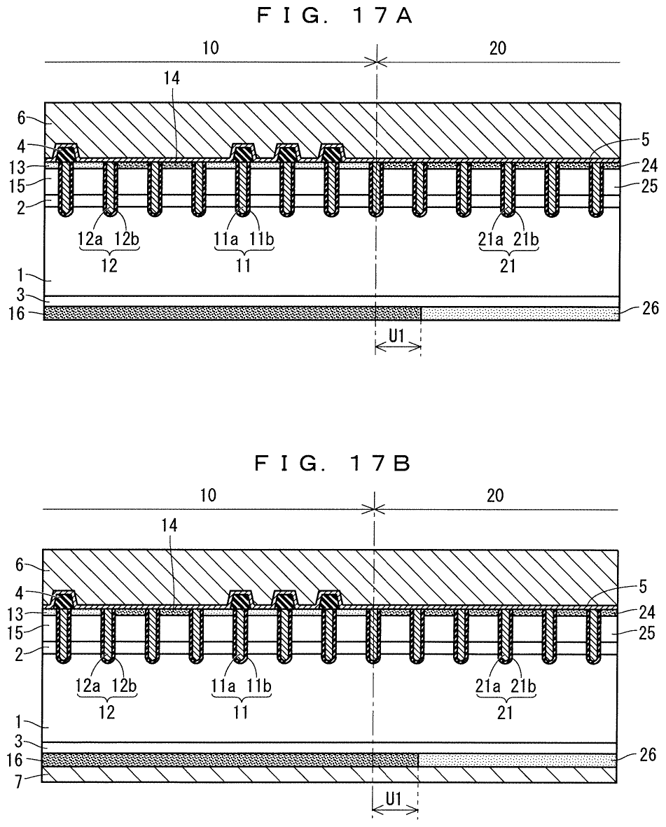

FIGS. 12A to 17B are cross-sectional views illustrating a method of manufacturing a semiconductor device that is an RC-IGBT. FIGS. 12A to 15B illustrate steps of mainly forming the front surface of the semiconductor device 100 in the boundary region in FIG. 9. FIGS. 16 and 17 illustrate steps of mainly forming the back surface of the semiconductor device 100 in the boundary region in FIG. 9.

As illustrated in FIG. 12A, a semiconductor substrate including the n⁻ type drift layer 1 is prepared. The semiconductor substrate may be, for example, an floating zone (FZ) wafer fabricated in the FZ method, a magnetic field-applied Czochralski (MCZ) wafer fabricated in the MCZ method, or an n-type wafer containing n-type impurities. The concentration of the n-type impurities contained in the semiconductor substrate are appropriately selected according to a breakdown voltage of a semiconductor device to be fabricated. For example, the concentration of the n-type impurities is adjusted so that the specific electrical resistance of the n⁻ type drift layer 1 included in the semiconductor substrate ranges approximately from 40 to 120 Ω·cm. As illustrated in FIG. 12A, the whole semiconductor substrate is the n⁻ type drift layer 1 in the step of preparing the semiconductor substrate. Ion implanting p-type or n-type impurities from the front surface that is the first main surface of the semiconductor substrate or the back surface that is the second main surface of the semiconductor substrate and then diffusing the ions into the semiconductor substrate through, for example, heat treatment appropriately form a p-type or n-type semiconductor layer and manufacture the semiconductor device 100.

As illustrated in FIG. 12A, the semiconductor substrate including the n⁻ type drift layer 1 includes regions to be the IGBT region 10 and the diode region 20. Furthermore, the semiconductor substrate includes a region to be the terminal region 30 around the regions to be the IGBT region 10 and the diode region 20, which is not illustrated in FIG. 12A. A method of manufacturing a structure of the IGBT region 10 and the diode region 20 in the semiconductor device 100 will be hereinafter mainly described. The terminal region 30 in the semiconductor device 100 may be fabricated in a known manufacturing method. For example, when the FLR including the p-type terminal well layers 31 is formed in the terminal region 30 as the breakdown voltage maintaining structure, p-type impurities may be ion implanted to form the FLR before the IGBT region 10 and the diode region 20 in the semiconductor device 100 are treated. Alternatively, the p-type impurities may be ion implanted to form the FLR simultaneously when p-type impurities are ion implanted into the IGBT region 10 or the diode region 20 in the semiconductor device 100.

Then, the n-type carrier storage layer 2 is formed by implanting n-type impurities such as phosphorus (P) from the front surface of the semiconductor substrate as illustrated in FIG. 12B. Furthermore, the p-type base layer 15 and the p-type anode layer 25 are formed by implanting p-type impurities such as boron (B) from the front surface of the semiconductor substrate. The n-type carrier storage layer 2, the p-type base layer 15, and the p-type anode layer 25 are formed by ion implanting impurities into the semiconductor substrate and then diffusing the impurities into the semiconductor substrate through heat treatment. Since n-type or p-type impurities are ion implanted after a masking process is applied on the front surface of the semiconductor substrate, various layers are selectively formed on the front surface of the semiconductor substrate. The n-type carrier storage layer 2, the p-type base layer 15, and the p-type anode layer 25 are formed in the IGBT region 10 and the diode region 20, and are connected to the p-type terminal well layers 31 in the terminal region 30. The masking process is a process of forming a mask on a semiconductor substrate by applying a resist on the semiconductor substrate and forming an opening in a predetermined region of the resist through photolithography so that ions are implanted into the predetermined region of the semiconductor substrate through the opening or the predetermined region is etched through the opening.

P-type impurities may be ion implanted simultaneously into the p-type base layer 15 and the p-type anode layer 25. Here, the p-type base layer 15 and the p-type anode layer 25 match in depth and p-type impurity concentration. Furthermore, the p-type base layer 15 and the p-type anode layer 25 may differ in depth and p-type impurity concentration by ion implanting p-type impurities separately into the p-type base layer 15 and the p-type anode layer 25 through the masking process.

The p-type impurities may be implanted simultaneously into the p-type anode layer 25 and the p-type terminal well layers 31 in the terminal region 30 which are not illustrated in FIG. 12B. Here, the p-type terminal well layers 31 and the p-type anode layer 25 match in depth and p-type impurity concentration. Ion implanting p-type impurities simultaneously into the p-type terminal well layers 31 and the p-type anode layer 25 using masks with different aperture ratios can give the p-type terminal well layers 31 and the p-type anode layer 25 different p-type impurity concentrations. Here, application of a mesh-shaped mask as one of or each of the masks allows the masks to have the different aperture ratios.

Furthermore, the p-type terminal well layers 31 and the p-type anode layer 25 may differ in depth and p-type impurity concentration by ion implanting p-type impurities separately into the p-type terminal well layers 31 and the p-type anode layer 25 through the masking process. Similarly, p-type impurities may be ion implanted simultaneously into the p-type terminal well layers 31, the p-type base layer 15, and the p-type anode layer 25 using masks with different aperture ratios.

Next, selectively implanting n-type impurities into the front surface of the p-type

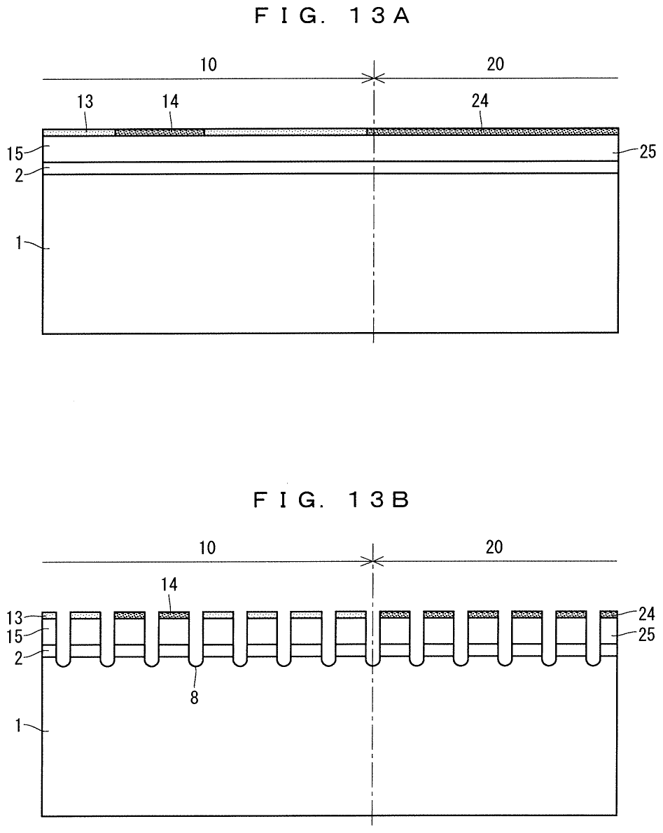

base layer 15 in the IGBT region 10 through the masking process forms the n⁺ type source layer 13 as illustrated in FIG. 13A. Examples of the n-type impurities to be implanted may include arsenic (As) and phosphorus (P). Furthermore, selectively implanting p-type impurities into the front surface of the p-type base layer 15 in the IGBT region 10 through the masking process forms the p⁺ type contact layer 14. In addition, selectively implanting p-type impurities into the front surface of the p-type anode layer 25 in the diode region 20 through the masking process forms the p⁺ type contact layer 24. Examples of the p-type impurities to be implanted may include boron (B) and aluminum (Al).

Then, trenches 8 penetrating the p-type base layer 15 and the p-type anode layer 25 from the front surface of the semiconductor substrate and reaching the n⁻ type drift layer 1 are formed as illustrated in FIG. 13B. Sidewalls of the trenches 8 penetrating the n⁺ type source layer 13 include a part of the n⁺ type source layer 13 in the IGBT region 10. The sidewalls of the trenches 8 penetrating the p⁺ type contact layer 14 include a part of the p⁺ type contact layer 14 in the IGBT region 10. The sidewalls of the trenches 8 penetrating the p⁺ type contact layer 24 include a part of the p⁺ type contact layer 24 in the diode region 20.

The trenches 8 are formed by, for example, depositing an oxide film made of SiO₂ on the semiconductor substrate, forming, through the masking process, an opening on a part of the oxide film into which the trenches 8 are to be formed, and etching the semiconductor substrate using the oxide film with the formed opening as a mask. Although the trenches 8 are formed at equal intervals in the IGBT region 10 and the diode region 20 in FIG. 13B, the trenches 8 may be formed at different intervals in the IGBT region 10 and the diode region 20. The intervals and the pattern of the trenches 8 in a plan view can be appropriately changed according to a mask pattern in the masking process.

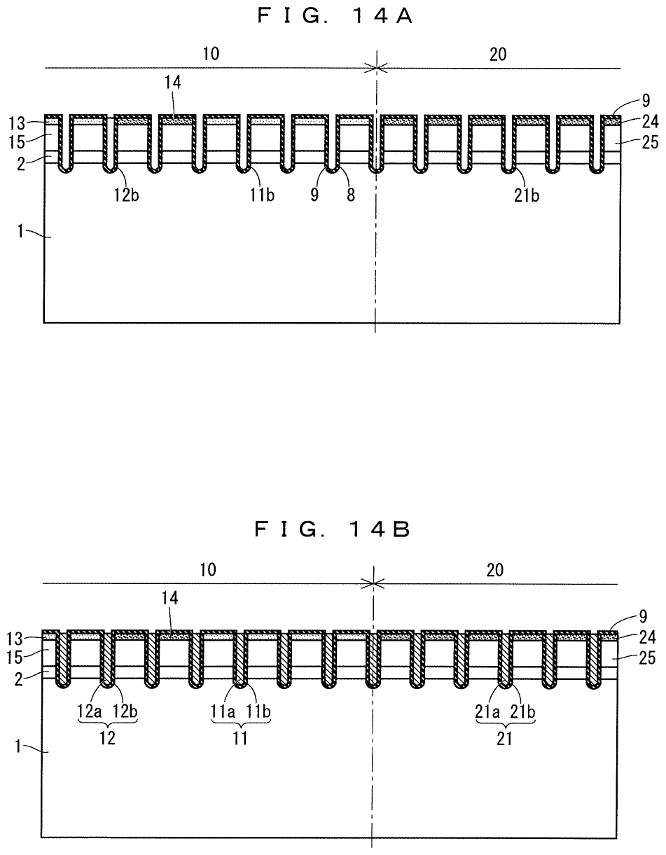

Next, heating the semiconductor substrate in an atmosphere containing oxygen forms an oxide film 9 on inner walls of the trenches 8 and the front surface of the semiconductor substrate as illustrated in FIG. 14A. The oxide film 9 formed on the trenches 8 in the IGBT region 10 becomes the gate trench insulating films 11b of the active trench gates 11 and the dummy trench insulating films 12b of the dummy trench gates 12. The oxide film 9 formed on the trenches 8 in the diode region 20 becomes the diode trench insulating films 21b. The portion of the oxide film 9 formed on the front surface of the semiconductor substrate is removed in the latter process except the portion formed on the trenches 8.

Then, depositing polysilicon doped with n-type or p-type impurities on the oxide film 9 in the trenches 8, for example, in the chemical vapor deposition (CVD) forms the gate trench electrodes 11a, the dummy trench electrodes 12a, and the diode trench electrodes 21a as illustrated in FIG. 14B.

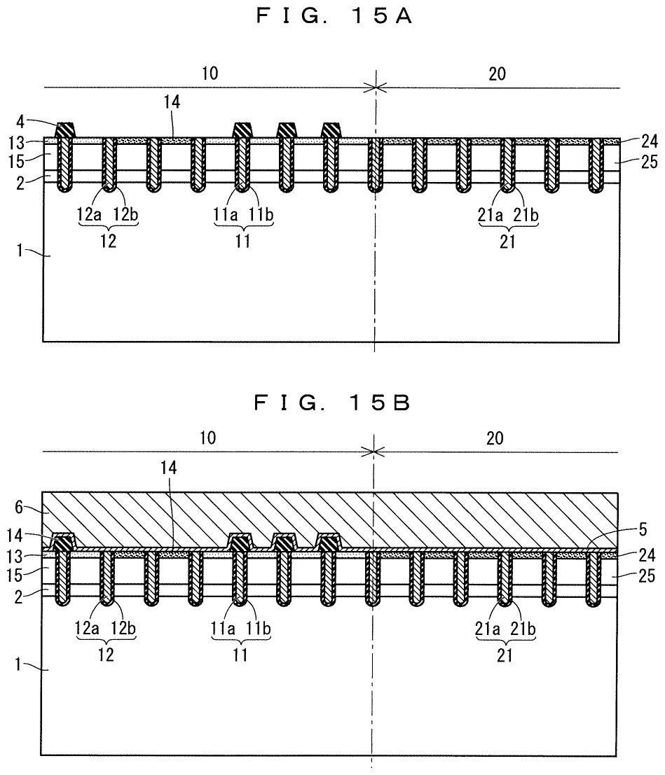

Next, the interlayer insulating film 4 is formed on the gate trench electrodes 11a of the active trench gates 11 in the IGBT region 10 as illustrated in FIG. 15A. The interlayer insulating film 4 may be made of, for example, SiO₂. Forming contact holes in an insulating film to be the deposited interlayer insulating film 4 and removing the oxide film 9 formed on the front surface of the semiconductor substrate through the masking process produce, for example, the interlayer insulating film 4 in FIG. 15A. The contact holes in the interlayer insulating film 4 are formed on the n⁺ type source layer 13, the p⁺ type contact layer 14, the p⁺ type contact layer 24, the dummy trench electrodes 12a, and the diode trench electrodes 21a.

Next, the barrier metal 5 is formed on the front surface of the semiconductor substrate and the interlayer insulating film 4, and the emitter electrode 6 is further formed on the barrier metal 5 as illustrated in FIG. 15B. The barrier metal 5 is formed by depositing a film of titanium nitride by physical vapor deposition (PVD) or CVD.

The emitter electrode 6 may be formed by depositing, for example, an alloy of aluminum and silicon (Al—Si based alloy) on the barrier metal 5 by sputtering or vapor deposition such as PVD. Further forming a nickel alloy (Ni alloy) on the formed alloy of aluminum and silicon by electroless plating or electroplating may form the emitter electrode 6. When the emitter electrode 6 is formed by plating, a thick metal film can be easily formed as the emitter electrode 6. This can increase the thermal capacity of the emitter electrode 6, and thereby improve the heat resistance. When the emitter electrode 6 made of an alloy of aluminum and silicon is formed by PVD and then a nickel alloy is further formed by plating on the emitter electrode 6, the plating for forming the nickel alloy may be performed after the back surface of the semiconductor substrate is treated.

Next, grinding the back surface of the semiconductor substrate thins the semiconductor substrate to a designed predetermined thickness as illustrated in FIG. 16A. The thickness of the ground semiconductor substrate may range, for example, from 80 μm to 200 μm.

Next, implanting n-type impurities from the back surface of the semiconductor substrate forms the n-type buffer layer 3 as illustrated in FIG. 16B. Then, implanting p-type impurities from the back surface of the semiconductor substrate forms the p-type collector layer 16. The n-type buffer layer 3 may be formed in, for example, the IGBT region 10, the diode region 20, and the terminal region 30, or formed only in the IGBT region 10 or the diode region 20. The n-type buffer layer 3 may be formed by implanting, for example, phosphorus (P) ion, proton (H⁺), or both proton and phosphorus. Proton can be implanted from the back surface of the semiconductor substrate to a depth with relatively low acceleration energy. Furthermore, changing the acceleration energy can relatively easily change the depth at which proton is implanted. Thus, when the n-type buffer layer 3 is formed from proton, implanting proton a plurality of times while the acceleration energy is being changed can form the n-type buffer layer 3 thicker in the thickness direction of the semiconductor substrate than that formed from phosphorus.

Since phosphorus can increase an activation ratio of n-type impurities more than that by proton, forming the n-type buffer layer 3 from phosphorus can suppress punch-through of a depletion layer even in the thinned semiconductor substrate. To further thin the semiconductor substrate, it is preferred to form the n-type buffer layer 3 by implanting both proton and phosphorus. Here, proton is implanted deeper than phosphorus from the back surface.

The p-type collector layer 16 may be formed by implanting, for example, boron (B). The p-type collector layer 16 is also formed in the terminal region 30 as the p-type terminal collector layer 16a. Irradiating the back surface of the semiconductor substrate in which ions have been implanted with laser light to laser anneal the back surface activates the implanted ions and forms the p-type collector layer 16.

When phosphorus is implanted at a relatively shallow depth from the back surface of the semiconductor substrate, the laser annealing simultaneously activates phosphorus. Proton is activated at a relatively low annealing temperature ranging from 350° C. to 500° C. When proton is implanted, it is necessary to prevent the temperature of the whole semiconductor substrate from becoming higher than 350° C. to 500° C. in the latter steps other than the step of activating proton. Since the laser annealing can increase the temperature of only the vicinity of the back surface of the semiconductor substrate, the laser annealing is applicable to activation of n-type impurities or p-type impurities even after proton is implanted.

Next, the n⁺ type cathode layer 26 is formed on the back surface in the diode region 20 as illustrated in FIG. 17A. The n⁺ type cathode layer 26 may be formed by implanting, for example, phosphorus (P). As illustrated in FIG. 17A, n-type impurities are selectively implanted from the back surface through the masking process so that a boundary between the p-type collector layer 16 and the n⁺ type cathode layer 26 is located at the distance U1 from the boundary between the IGBT region 10 and the diode region 20 toward the diode region 20. The amount of n-type impurities for forming the n⁺ type cathode layer 26 is larger than that of p-type impurities for forming the p-type collector layer 16. Thus, the n⁺ type cathode layer 26 is deeper than the p-type collector layer 16. The region in which the n⁺ type cathode layer 26 is to be formed need to be changed into an n-type semiconductor by implanting n-type impurities in a region in which p-type impurities have been implanted. Thus, n-type impurities are higher in concentration than p-type impurities in the whole region in which the n⁺ type cathode layer 26 is to be formed.

Next, the collector electrode 7 is disposed on the back surface of the semiconductor substrate as illustrated in FIG. 17B. The collector electrode 7 is disposed on the whole back surface of, for example, the IGBT region 10, the diode region 20, and the terminal region 30. The collector electrode 7 may also be formed on the whole back surface of an n-type wafer that is a semiconductor substrate. The collector electrode 7 may be formed by depositing, for example, an alloy of aluminum and silicon (Al—Si based alloy) or titanium (Ti) by sputtering or vapor deposition such as PVD, or by laminating a plurality of metals including the alloy of aluminum and silicon, titanium, nickel, and gold. Further forming a metal film by electroless plating or electroplating on the metal film formed by PVD may form the collector electrode 7.

The aforementioned steps fabricate the semiconductor device 100. A plurality of the semiconductor devices 100 are normally fabricated in a matrix in an integrated manner on a semiconductor substrate such as a single n-type wafer. Thus, the semiconductor devices 100 are cut into pieces by laser dicing or blade dicing.

### Polysilicon Element

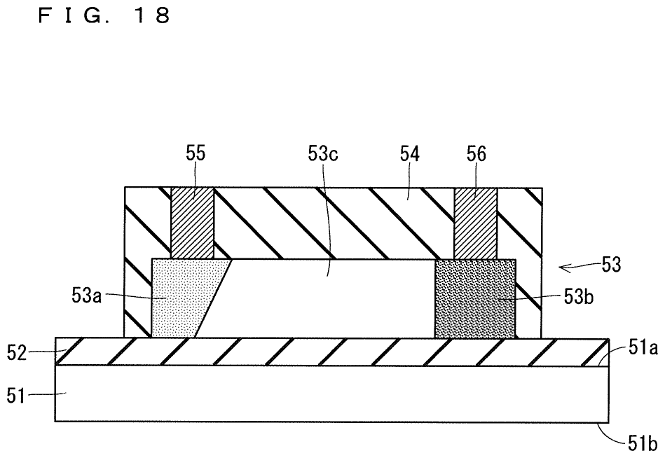

FIG. 18 is a cross-sectional view illustrating a structure of a semiconductor device according to Embodiment 1. The semiconductor device according to Embodiment 1includes the aforementioned RC-IGBT and a polysilicon element to be described hereinafter.

The semiconductor device in FIG. 18 includes a semiconductor substrate 51, a lower insulating film 52 that is a first insulating film, a polysilicon element 53, an upper insulating film 54 that is a second insulating film, a cathode electrode 55, and an anode electrode 56.

The semiconductor substrate 51, which is the semiconductor substrate previously described in the structure of the RC-IGBT, has a front surface 51a that is a first main surface and a back surface 51b that is a second main surface, and includes an energization region. In the energization region, a first electrode is disposed closer to the front surface 51a, and a second electrode is disposed closer to the back surface 51b. The energization region according to Embodiment 1 corresponds to the IGBT region 10 and the diode region 20 in FIG. 9 through which the main current of the RC-IGBT flows. The first electrode corresponds to the emitter electrode 6 in FIG. 9, and the second electrode corresponds to the collector electrode 7 in FIG. 9. Although the energization region, the first electrode, and the second electrode are described as the constituent elements in FIG. 9 for convenience, they may be the constituent elements in, for example, FIG. 4, 5, 7, or 8.

The polysilicon element 53 is formed on the front surface 51a of the semiconductor substrate 51 through the lower insulating film 52. For example, the polysilicon element 53 is formed in a region other than the IGBT region 10 and the diode region 20, that is, a region such as the terminal region 30 and the pad region 40 in FIGS. 1 and 2. The lower insulating film 52 may be, for example, a CVD film or a thermal oxide film.

The polysilicon element 53 includes an n⁺ type cathode region 53a that is a first region of a first conductivity type, a p⁺ type anode region 53b that is a second region of a second conductivity type, and a p⁻ type drift region 53c that is a third region of the second conductivity type. The n⁺ type cathode region 53a, the p⁺ type anode region 53b, and the p⁻ type drift region 53c are formed on the lower insulating film 52.

The n⁺ type cathode region 53a may be identical in impurity concentration to the n⁺ type source layer 13 in FIG. 9, and the p⁺ type anode region 53b may be identical in impurity concentration to the p⁺ type contact layer 14 in FIG. 9. The p⁻ type drift region 53c is lower in impurity concentration than the p⁺ type anode region 53b, and is disposed between the n⁺ type cathode region 53a and the p⁺ type anode region 53b.

The upper insulating film 54 covers at least the top of the polysilicon element 53, that is, covers a portion other than the lower portion of the polysilicon element 53 in Embodiment 1. Furthermore, the aforementioned lower insulating film 52 has a thickness less than or equal to that of the upper insulating film 54 in Embodiment 1. The upper insulating film 54 may be, for example, a CVD film made of SiO₂. The upper insulating film 54 has a contact hole that exposes the n⁺ type cathode region 53a and a contact hole that exposes the p⁺ type anode region 53b.

The cathode electrode 55 is electrically connected to the n⁺ type cathode region 53a through the contact hole that exposes the n⁺ type cathode region 53a. The anode electrode 56 is electrically connected to the p⁺ type anode region 53b through the contact hole that exposes the p⁺ type anode region 53b.

The polysilicon element 53 with such a structure functions as a diode that conducts electricity in a surface direction. The polysilicon element 53 may be a temperature sensing diode or a Zener diode.

As illustrated in FIG. 18, the width of the n⁺ type cathode region 53a in a cross-sectional view, that is, the length in the surface direction varies in an upward direction that is a direction from the back surface 51b toward the front surface 51a of the semiconductor substrate 51. In the example of FIG. 18, continuously and monotonously increasing the width of the n⁺ type cathode region 53a in the upward direction in the cross-sectional view allows the n⁺ type cathode region 53a to have a tapered shape that is tapered downward.

### Method of Manufacturing Polysilicon Element

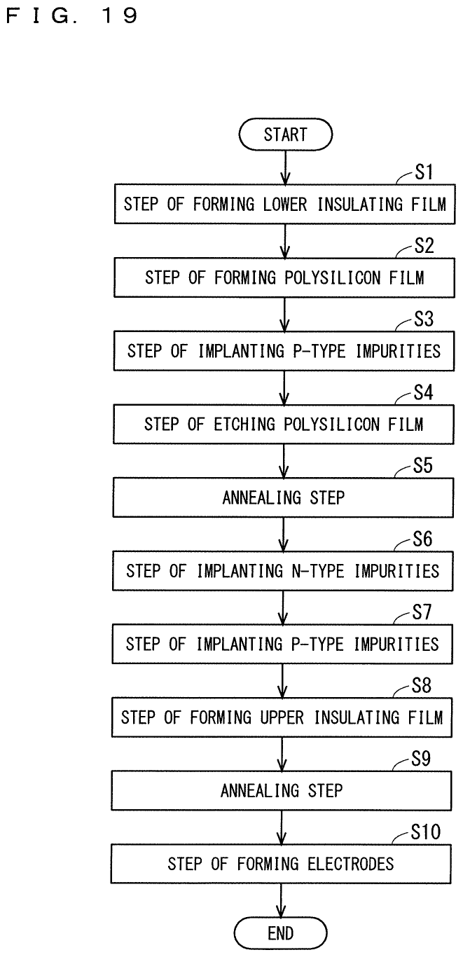

FIG. 19 is a flowchart illustrating a method of manufacturing the polysilicon element 53 according to Embodiment 1. The manufacturing method in FIG. 19 is performed after the semiconductor substrate 51 with the front surface 51a and the back surface 51b is prepared. The RC-IGBT need not be completed on the semiconductor substrate 51 at the time of starting the manufacturing method in FIG. 19. The polysilicon element 53 and the RC-IGBT may be manufactured simultaneously.

In Step S1, the lower insulating film 52 is formed on the front surface 51a of the semiconductor substrate 51. In Step S2, a polysilicon film is uniformly formed on the lower insulating film 52. The thickness of the polysilicon film may be, for example, less than or equal to 700 nm or less than or equal to 500 nm.

In Step S3, p-type impurities are ion implanted into the polysilicon film. Examples of the p-type impurities include boron (B) and aluminum (Al). In Step S4, the polysilicon film is etched into the shape of the polysilicon element 53 in FIG. 18. In Step S5, annealing is performed to diffuse, into the polysilicon film, the p-type impurities implanted into the polysilicon film. This completes a step of forming, on the lower insulating film 52, a p-type polysilicon film substantial identical in contour to the polysilicon element 53.

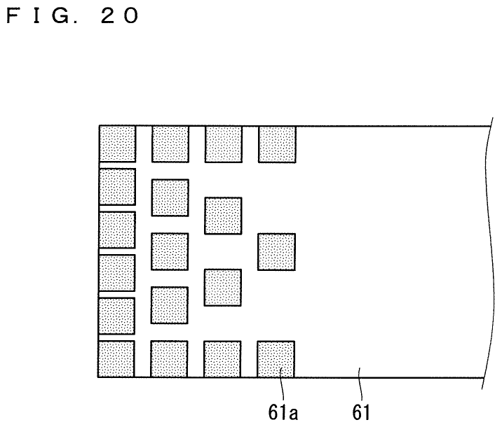

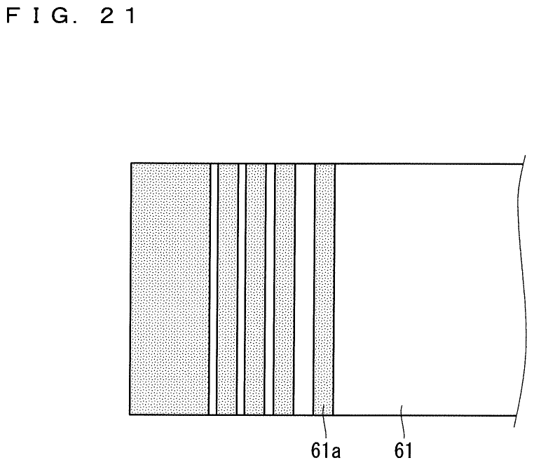

In Step S6, n-type impurities are ion implanted into a first end of the polysilicon film. Examples of the n-type impurities include arsenic (As) and phosphorus (P). A resist mask with an aperture ratio increasing from the center toward the first end of the polysilicon film is used in the ion implantation in Step S6 according to Embodiment 1.This consequently increases, for example, a rate per area of regions 61a into which n-type impurities are ion implanted from the center toward the first end of a polysilicon film 61 as illustrated in FIGS. 20 and 21.

In Step S7, p-type impurities are ion implanted into a second end opposite to the first end of the polysilicon film. This completes the step of implanting n-conductive type impurities and p-conductive type impurities into the first end and the second end, respectively, that are separate portions in the polysilicon film 61.

In Step S8, the upper insulating film 54 covering the polysilicon film 61 is formed. In Step S9, annealing the upper insulating film 54 and the polysilicon film 61 diffuses impurities into the polysilicon film 61 while planarizing the upper insulating film 54 to form the n⁺ type cathode region 53a, the p⁺ type anode region 53b, and the p⁻0 type drift region 53c in the polysilicon film 61. Since the rate per area of the regions 61a into which n-type impurities are ion implanted in Step S6 increases toward the first end, the width of the n⁺ type cathode region 53a in a cross-sectional view varies in the upward direction as illustrated in FIG. 18.

The temperature of the annealing in Step S9 is, for example, higher than or equal to 700° C. and lower than or equal to 1100° C., or higher than or equal to 800° C. and lower than or equal to 900° C., and the time for the annealing is, for example, 60 minutes. The annealing in Step S9 is performed in an atmosphere containing, for example, at least one of N₂, O₂, or H₂. When the n-type buffer layer 3 is formed by ion implanting proton in FIG. 16B, the annealing in Step S9 is preferably performed before forming the n-type buffer layer 3.

In Step S10, contact holes are formed in the upper insulating film 54 to form the cathode electrode 55 and the anode electrode 56.

### Conclusion of Embodiment 1

In the semiconductor device according to Embodiment 1, the width of the n⁺ type cathode region 53a in a cross-sectional view varies in the upward direction that is a direction from the back surface 51b toward the front surface 51a of the semiconductor substrate 51. Such a structure can increase a junction area of a p-n junction more than a structure in which a boundary of a p-n junction in a cross-sectional view extends in the vertical direction without any slope. Consequently, when the polysilicon element 53 is a temperature sensing diode, a forward voltage of the temperature sensing diode can be reduced. When the polysilicon element 53 is a Zener diode, a breakdown voltage of the Zener diode can be increased.

The aforementioned structure can increase the junction area of the p-n junction, without increasing the area of the polysilicon element 53 in a plan view or thickening the polysilicon element 53. Thus, the junction area of the p-n junction can be increased, without reducing an effective region that is at least one of the IGBT region 10 or the diode region 20 or increasing the time for diffusing impurities.

Furthermore, the lower insulating film 52 has a thickness less than or equal to that of the upper insulating film 54 in Embodiment 1. For example, when the polysilicon element 53 is a temperature sensing diode, this structure allows the temperature sensing diode to be closer to the semiconductor substrate 51. Thus, the temperature of an element in the energization region can be accurately detected.

In Embodiment 1, annealing the upper insulating film 54 and the polysilicon film 61 planarizes the upper insulating film 54 and forms the n⁺ type cathode region 53a, the p⁺ type anode region 53b, and the p⁻ type drift region 53c in the polysilicon film 61. Since such a structure does not require dedicated annealing for diffusing impurities to form, for example, the n⁺ type cathode region 53a, we can expect reduction in the manufacturing cost.

The thickness of the polysilicon film 61 is less than or equal to 500 nm in Embodiment 1. Since such a structure can reduce the time for forming the polysilicon film 61, and the annealing time and the annealing temperature for diffusing impurities to form, for example, the n⁺ type cathode region 53a, we can expect reduction in the manufacturing cost.

### Modifications

In Embodiment 1, a rate per area of the regions 61a into which ions are implanted is increased as illustrated in FIGS. 20 and 21, using a resist mask with an aperture ratio increasing from the center toward the first end of the polysilicon film in the ion implantation in Step S6. However, formation of the n⁺ type cathode region 53a whose width varies in a cross-sectional view is not limited to this method. For example, n-type impurities may be implanted into the first end of the polysilicon film, using a resist mask that opens the whole first end and using an angled ion implantation in Step S6. This method can also form the n⁺ type cathode region 53a whose width varies in a cross-sectional view. Furthermore, adjustment of reducing the temperature of the heat treatment for diffusing impurities or shortening the time for the heat treatment in Step S6 can form the n⁺ type cathode region 53a whose width varies in a cross-sectional view even when ions are implanted almost in the vertical direction.

Although the n⁺ type cathode region 53a has a tapered shape that is tapered downward with continuous and monotonous increase in the width of the n⁺ type cathode region 53a in a cross-sectional view in Embodiment 1, variation in the width is not limited to this. For example, the width of the n⁺ type cathode region 53a in a cross-sectional view may vary stepwise upward. This structure can further increase the junction area of the p-n junction.

For example, the width of the n⁺ type cathode region 53a in a cross-sectional view need not increase upward but may decrease upward. Furthermore, a combination of the aforementioned method with, for example, the angled ion implantation allows the width of the n⁺ type cathode region 53a in a cross-sectional view to decrease and then increase upward, or increase and then decrease upward.

For example, the impurity concentration of the n⁺ type cathode region 53a may have an upward gradient. For example, the impurity concentration of the n⁺ type cathode region 53a in the structure in FIG. 18 according to Embodiment 1 may increase upward. This structure can further increase an angle at which the boundary of the p-n junction is sloped in the vertical direction, and consequently further increase the junction area of the p-n junction.

Furthermore, the width of the p⁺ type anode region 53b in a cross-sectional view may vary upward, similarly to the width of the n⁺ type cathode region 53a. Since this structure can substantially increase the width of the p⁻ type drift region 53c, an adjustment range on output characteristics of the polysilicon element 53 can be widened.

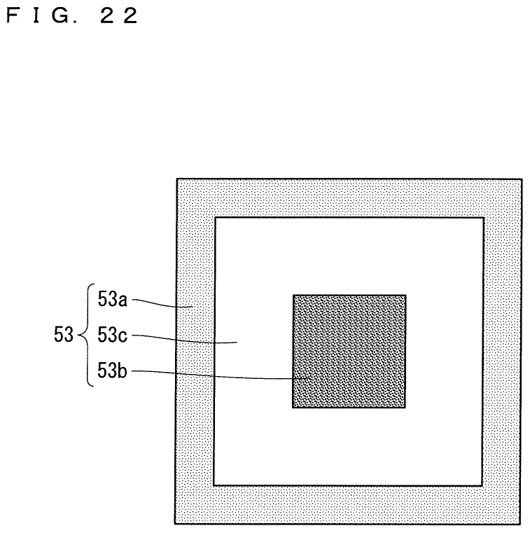

Although the n⁺ type cathode region 53a and the p⁺ type anode region 53b are formed in the first end and the second end of the polysilicon film 61, respectively, in the structure of FIG. 18, the formation is not limited to this. For example, the n⁺ type cathode region 53a may surround the p⁺ type anode region 53b through the p⁻ type drift region 53c in a plan view as illustrated in FIG. 22.

Although the RC-IGBT including the IGBT region 10 and the diode region 20 is formed in the energization region in Embodiment 1, the energization region is not limited to this. For example, the energization region may include one of the IGBT region 10 and the diode region 20, or at least one of a metal-oxide semiconductor field-effect transistor (MOSFET), an insulated-gate bipolar transistor (IGBT), a Schottky barrier diode (SBD), or a PN junction diode (PND).

The details of the embodiments can be appropriately modified or omitted.

A summary of various aspects of the present disclosure will be hereinafter described as Appendixes.

### Appendix 1

A semiconductor device, comprising:
a semiconductor substrate having a first main surface and a second main surface; and
a polysilicon element formed on the first main surface through a first insulating film,
the semiconductor substrate including an energization region in which a first electrode is disposed closer to the first main surface and a second electrode is disposed closer to the second main surface,
the polysilicon element including:
a first region of a first conductivity type and a second region of a second conductivity type, the first region and the second region being formed on the first insulating film; and
a third region of the second conductivity type between the first region and the second region, the third region being lower in impurity concentration than the second region,
wherein a width of the first region in a cross-sectional view varies in a direction from the second main surface to the first main surface.

[Appendix 2] The semiconductor device according to appendix 1,
wherein variation of the width of the first region in the cross-sectional view in the direction allows the first region to have a tapered shape.

[Appendix 3] The semiconductor device according to appendix 1,
wherein the width of the first region in the cross-sectional view varies stepwise in the direction.

[Appendix 4] The semiconductor device according to any one of appendixes 1 to 3,
wherein an impurity concentration of the first region has a gradient in the direction.

[Appendix 5] The semiconductor device according to any one of appendixes 1to 4,
wherein the polysilicon element is a temperature sensing diode or a Zener diode.

[Appendix 6] The semiconductor device according to any one of appendixes 1to 5,
wherein the energization region is at least one of an insulated gate bipolar transistor region or a diode region.

[Appendix 7] The semiconductor device according to any one of appendixes 1to 6, further comprising
a second insulating film covering at least a top of the polysilicon element,
wherein the first insulating film has a thickness less than or equal to a thickness of the second insulating film.

[Appendix 8] The semiconductor device according to any one of appendixes 1to 7,
wherein a width of the second region in the cross-sectional view varies in the direction.

[Appendix 9] A method of manufacturing a semiconductor device, the method comprising the steps of:
preparing a semiconductor substrate having a first main surface and a second main surface;
forming a first insulating film on the first main surface;
forming a polysilicon film of a second conductivity type on the first insulating film;
implanting impurities of a first conductivity type and impurities of the second conductivity type into separate portions in the polysilicon film;
forming a second insulating film covering at least a top of the polysilicon film; and
annealing the second insulating film and the polysilicon film to planarize the second insulating film and form, in the polysilicon film, a first region of the first conductivity type, a second region of the second conductivity type, and a third region of the second conductivity type between the first region and the second region, the third region being lower in impurity concentration than the second region,
wherein a width of the first region in a cross-sectional view varies in a direction from the second main surface to the first main surface.

[Appendix 10] The method according to appendix 9,
wherein a thickness of the polysilicon film is less than or equal to 500 nm.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a semiconductor substrate having a first main surface and a second main surface; and
a polysilicon element formed on the first main surface through a first insulating film,
the semiconductor substrate including an energization region in which a first electrode is disposed closer to the first main surface and a second electrode is disposed closer to the second main surface,
the polysilicon element including:
a first region of a first conductivity type and a second region of a second conductivity type, the first region and the second region being formed on the first insulating film; and
a third region of the second conductivity type between the first region and the second region, the third region being lower in impurity concentration than the second region,
wherein a width of the first region in a cross-sectional view varies in a direction from the second main surface to the first main surface.

2. The semiconductor device according to claim 1,
wherein variation of the width of the first region in the cross-sectional view in the direction allows the first region to have a tapered shape.

3. The semiconductor device according to claim 1,
wherein the width of the first region in the cross-sectional view varies stepwise in the direction.

4. The semiconductor device according to claim 1,
wherein an impurity concentration of the first region has a gradient in the direction.

5. The semiconductor device according to claim 1,
wherein the polysilicon element is a temperature sensing diode or a Zener diode.

6. The semiconductor device according to claim 1,
wherein the energization region is at least one of an insulated gate bipolar transistor region or a diode region.

7. The semiconductor device according to claim 1, further comprising
a second insulating film covering at least a top of the polysilicon element,
wherein the first insulating film has a thickness less than or equal to a thickness of the second insulating film.

8. The semiconductor device according to claim 1,
wherein a width of the second region in the cross-sectional view varies in the direction.

9. A method of manufacturing a semiconductor device, the method comprising the steps of:
preparing a semiconductor substrate having a first main surface and a second main surface;
forming a first insulating film on the first main surface;
forming a polysilicon film of a second conductivity type on the first insulating film;
implanting impurities of a first conductivity type and impurities of the second conductivity type into separate portions in the polysilicon film;
forming a second insulating film covering at least a top of the polysilicon film; and
annealing the second insulating film and the polysilicon film to planarize the second insulating film and form, in the polysilicon film, a first region of the first conductivity type, a second region of the second conductivity type, and a third region of the second conductivity type between the first region and the second region, the third region being lower in impurity concentration than the second region,
wherein a width of the first region in a cross-sectional view varies in a direction from the second main surface to the first main surface.

10. The method according to claim 9,
wherein a thickness of the polysilicon film is less than or equal to 500 nm.
